(19) United States
(12) Patent Application Publication
(10) Pub. No.: US 2015/0091047 A1
(43) Pub. Date: Apr. 2, 2015

(54) METHOD OF GROWING NITRIDE SEMICONDUCTOR, METHOD OF MANUFACTURING TEMPLATE FOR SEMICONDUCTOR FABRICATION AND METHOD OF MANUFACTURING SEMICONDUCTOR LIGHT EMITTING DEVICE USING THE SAME

(71) Applicant: Seoul Viosys Co., Ltd., Ansan-si (KR)

(72) Inventors: Seung Kyu Choi, Ansan-si (KR); Woo Chul Kwak, Ansan-si (KR); Chae Hon Kim, Ansan-si (KR); Jung Whan Jung, Ansan-si (KR); Sam Seok Jang, Ansan-si (KR)

(21) Appl. No.: 14/500,836

(22) Filed: Sep. 29, 2014

(30) Foreign Application Priority Data
Sep. 27, 2013 (KR) 1020130115497

(51) Int. Cl. H01L 33/00; H01L 33/32; H01L 33/02

(52) U.S. Cl. CPC H01L 33/0075; H01L 33/0095; H01L 33/025; H01L 33/32
USPC 257/103; 438/46

(57) ABSTRACT

Disclosed are a method of growing a nitride semiconductor, a method of manufacturing a template for semiconductor fabrication and a method of manufacturing a semiconductor light emitting device using the same. The method of manufacturing a semiconductor light emitting device includes: preparing a growth substrate having a defect aggregation region; growing a first nitride semiconductor layer over the growth substrate; growing a second nitride semiconductor layer over the first nitride semiconductor layer; growing a third nitride semiconductor layer over the second nitride semiconductor layer; growing an active layer over the third nitride semiconductor layer; and forming a second conductive type semiconductor layer over the active layer. Accordingly, semiconductor layers grown on the template can have excellent crystallinity.

### CROSS-REFERENCE TO RELATED APPLICATION

This patent document claims priority from and the benefit of Korean Patent Application No. 10-2013-0115497, filed on Sep. 27, 2013, the contents of which are hereby incorporated by reference in their entirety.

### BACKGROUND

The disclosure of this patent document relates to a technology for a method of growing a nitride semiconductor, a method of manufacturing a template for semiconductor fabrication, and a method of manufacturing a semiconductor light emitting device using the same. One implementation of this patent document relates to a method of manufacturing a template for semiconductor fabrication and a semiconductor light emitting device through a growth method capable of enhancing surface quality of a nitride semiconductor.

Light emitting devices, which are inorganic semiconductor devices emitting light generated by recombination of electrons and holes, are used in a variety of fields such as displays, vehicle lamps, general lighting devices, etc. For example, since nitride semiconductors such as a gallium nitride semiconductor and a gallium aluminum semiconductor can be of a direct transition type and can be manufactured to have various energy band gaps, the nitride semiconductors can be used to manufacture light emitting devices having various wavelength emission ranges as required. Semiconductor devices such as light emitting devices and electronic devices are manufactured using the advantages of the nitride semiconductors.

### SUMMARY

Aspects of this patent document provide a method of growing nitride semiconductor layers with excellent crystallinity using a nitride growth substrate containing defect aggregation regions.

In addition, aspects of this patent document provide a template for semiconductor fabrication and a semiconductor light emitting device with excellent crystallinity to be manufactured using the growth method.

Additional features of technology disclosed in this patent document will be set forth in the description which follows, and in part will be apparent from the description, or can be learned by practice of certain implementations of the disclosed technology.

In accordance with one aspect of the disclosed technology, a method of manufacturing a semiconductor light emitting device includes: preparing a growth substrate having a defect aggregation region; growing a first nitride semiconductor layer over the growth substrate; growing a second nitride semiconductor layer over the first nitride semiconductor layer; growing a third nitride semiconductor layer over the second nitride semiconductor layer; growing an active layer over the third nitride semiconductor layer; and forming a second conductive type semiconductor layer over the active layer, wherein the first and second nitride semiconductor layers are grown at a first temperature and a second temperature, respectively, and the first temperature is higher than the second temperature.

The method of manufacturing can be implemented in various ways to include one or more of the following features. The first and second nitride semiconductor layer can be grown at a first temperature and a second temperature, respectively.

The first temperature can be in the range of 1050° C. to 1200° C., and the second temperature may be in the range of 700° C. to 850° C.

The method may further includes performing a heat treating on the second nitride semiconductor layer at a third pressure and a third temperature.

The third temperature can be 1000° C. or higher.

The first, the second and the third pressures can be the same and the first pressure can be in the range of 50 Torr to 300 Torr.

The second pressure can be higher than the first or third pressures and can be in the range of 300 Torr to 500 Torr.

The method can further include growing a third nitride semiconductor layer on the second nitride semiconductor layer after heat treating the second nitride semiconductor layer, and the third nitride semiconductor layer can be grown at a fourth pressure and a fourth temperature.

The fourth pressure can be the same as the first pressure and the fourth temperature can be the same as the first temperature.

The first nitride semiconductor layer can include a pit formed on the defect aggregation region.

The second nitride semiconductor layer can fill the pit.

The second nitride semiconductor layer can be grown at a pressure of 300 Torr to 500 Torr, and the first nitride semiconductor layer can be grown at a lower pressure than the second nitride semiconductor layer.

After the performing of the heat treatment, the second nitride semiconductor layer can have a flat upper surface.

In some embodiments, the growth substrate can include a nitride substrate.

The nitride substrate can include non-polar or semi-polar properties.

The third nitride semiconductor layer can contain a first conductive type impurity to have first conductive type properties.

The growing of the third nitride semiconductor layer can include increasing a growth temperature of a process chamber after the growing of the second nitride semiconductor layer, wherein the second nitride semiconductor layer can be heat-treated while increasing a growth temperature of the process chamber.

In accordance with another aspect of the disclosed technology, a semiconductor fabrication template is provided to include a growth substrate including defect aggregation regions and a non-polar or a semi-polar growth plane; a first nitride semiconductor layer disposed over the growth substrate to form pits that in the defect aggregation regions; a second nitride semiconductor layer disposed over the first nitride semiconductor layer to fill the pits; a third nitride semiconductor layer disposed over the second nitride semiconductor layer and doped with impurities for determining a type of conductivity.

In some implementations, the second nitride semiconductor layer has a surface roughness higher than the first nitride semiconductor layer.

In some implementations, the template is substantially free of defects originated from the defect aggregation regions.

According to embodiments of the disclosed technology, propagation of defects from defect aggregation regions of a growth substrate can be prevented to provide a method of manufacturing a template for semiconductor fabrication with excellent surface quality. In addition, a method can be provided for fabricating semiconductor layers with excellent surface quality and crystallinity on the template. Further, a method can be provided for manufacturing a semiconductor light emitting device by growing a semiconductor layer on the template, and the semiconductor light emitting device can have excellent electrical properties.

### BRIEF DESCRIPTION OF DRAWINGS

The accompanying drawings, which are included to provide a further understanding of this patent document and are incorporated in and constitute a part of this specification, illustrate exemplary embodiments of the invention, and together with the description serve to explain the principles of the disclosed technology.

FIGS. 1 to 5 are sectional views illustrating an example of a method of manufacturing a template for semiconductor fabrication and a semiconductor light emitting device according to one embodiment of the disclosed technology.

FIG. 6 is a graph showing exemplary conditions for growth of semiconductor layers according to one embodiment of the disclosed technology.

FIG. 7 is a graph showing exemplary conditions for growth of semiconductor layers according to another embodiment of the disclosed technology.

FIGS. 8A and 8B are images illustrating a comparison between a surface of a semiconductor layer grown by a method of growing a nitride semiconductor according to the disclosed technology and a surface of a semiconductor layer grown according to a comparative example.

### DETAILED DESCRIPTION OF THE EXEMPLARY EMBODIMENTS

Hereinafter, embodiments of the disclosed technology will be described in detail with reference to implementation examples, including those illustrated in the accompanying drawings. The following embodiments are provided by way of examples so as to convey the disclosed technology to those skilled in the art to which the present invention pertains. Accordingly, the disclosure of this patent document is not limited to the embodiments disclosed herein and can be implemented in different forms. In the drawings, widths, lengths, thicknesses, and the like of elements can be exaggerated for convenience and illustrative purposes. Further, when an element is referred to as being “above” or “on” another element, it can be “directly above” or “directly on” the other element or intervening elements can be present. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Throughout drawings and corresponding description in the specification, like reference numerals denote like elements having the same or similar functions.

In the related art, a nitride semiconductor layer is grown mainly using a heterogeneous substrate such as a sapphire substrate as a growth substrate due to technical and economical limitations in manufacture of the homogeneous substrate as the nitride semiconductor. However, on account of problems caused by a difference in lattice constant and coefficient of thermal expansion between the heterogeneous substrate such as the sapphire substrate and nitride semiconductor material, limitations can exist in terms of efficiency and reliability of the nitride semiconductor layer grown on the heterogeneous substrate. Especially, high crystal defect density (e.g., dislocation density) of the nitride semiconductor layer grown on the heterogeneous substrate makes it difficult to manufacture a semiconductor device that can be operated under high current density.

As such, technologies have been recently developed for growing a nitride semiconductor layer using a homogeneous substrate such as a gallium nitride substrate or an aluminum nitride substrate as a growth substrate. The homogeneous substrate is manufactured by slicing a bulk nitride single crystal along a growth plane of the substrate or another plane orientation. The bulk nitride single crystal is generally grown on a sapphire substrate by Hydride Vapor Phase Epitaxy (HVPE) and has a c-plane as a growth plane.

A nitride semiconductor is known to be most stably grown on a c-plane, and thus a nitride semiconductor device having a nitride semiconductor layer grown on the c-plane is broadly used. However, the nitride semiconductor layer having the c-plane as the growth plane causes spontaneous polarization due to the polarity of the c-plane, and the nitride semiconductor layer grown on the heterogeneous substrate such as the sapphire substrate causes a piezoelectric effect due to strain generated by lattice mismatch. The spontaneous polarization and the piezoelectric effect causes the modification of an energy band gap to degrade internal quantum efficiency of the semiconductor device, and change an emission wavelength of a light emitting device.

In order to solve the aforementioned problems, a method of manufacturing a non-polar homogeneous substrate can be implemented.

The non-polar homogeneous substrate is manufactured by slicing the aforementioned bulk nitride single crystal along a plane orientation (e.g., a-plane or m-plane) other than the c-plane. However, the homogeneous substrate manufactured in this way is too small to be used for commercial purposes. Accordingly, a technology for manufacturing a large-area non-polar nitride substrate can be implemented by tiling small-sized non-polar nitride substrates as disclosed in Japanese Patent Publication No. 2003-165799, for example.

The non-polar nitride substrate disclosed in the Japanese patent document has defect aggregation regions formed at portions where the plural small-sized non-polar nitride substrates are combined with each other. For example, defect aggregation regions are formed to have a dot or stripe pattern depending on a method of manufacturing a substrate. A nitride semiconductor layer grown on the non-polar nitride substrate has defects propagated from the defect aggregation regions, and regions at which defects are concentrated do not function as a semiconductor device on account of coarse crystallinity of the semiconductor layer. In addition, when a semiconductor layer is two-dimensionally grown on the non-polar nitride substrate, pits are formed over the defect aggregation regions and degrades crystallinity of the semiconductor layer. As a result, fabrication yield is decreased and reliability of the manufactured semiconductor device is degraded.

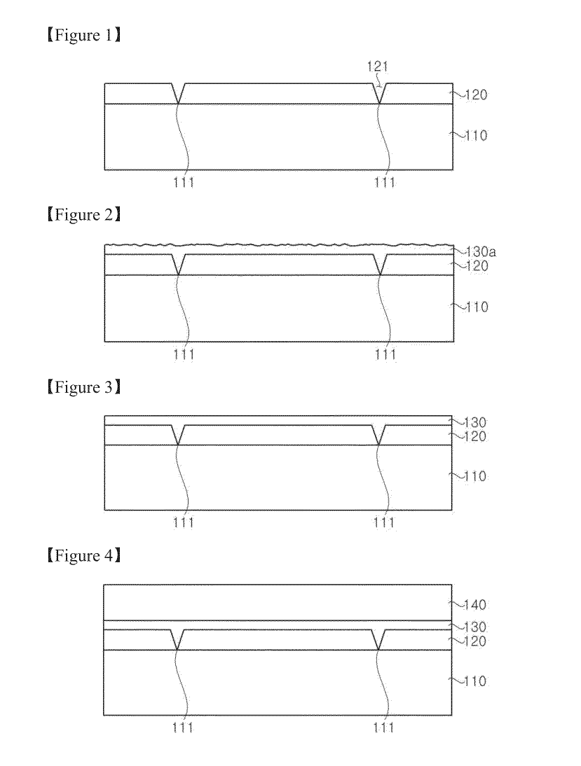

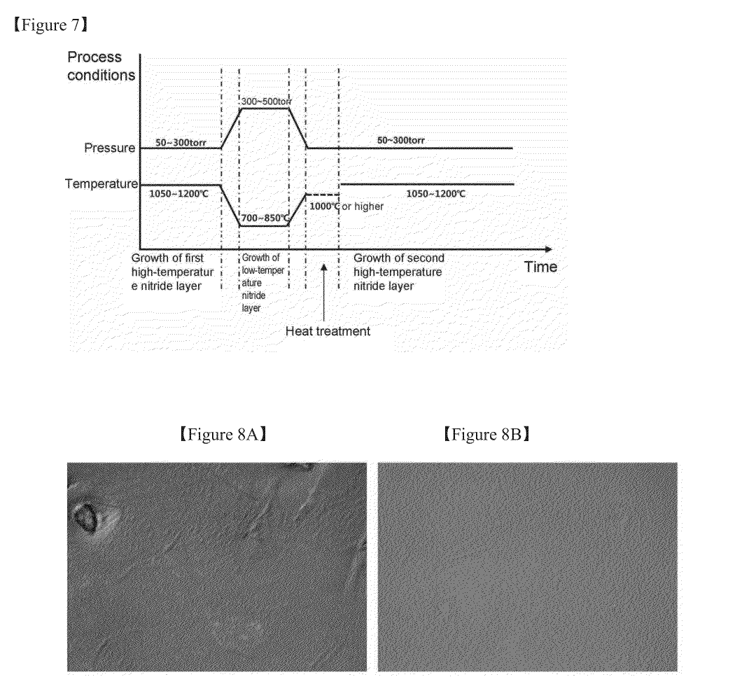

FIGS. 1 to 5 are cross-sectional views for illustrating an example of a method of manufacturing a template for semiconductor fabrication and a semiconductor light emitting device according to one embodiment of the disclosed technology, and FIGS. 6 and 7 are graphs showing exemplary conditions for growth of semiconductor layers according to embodiments of the disclosed technology. The conditions for growth of the semiconductor layers given with reference to FIGS. 6 and 7 are illustrative only, and the disclosed technology is not limited to the conditions shown in FIGS. 6 and 7.

Referring to FIG. 1, a growth substrate 110 is prepared, and a first nitride semiconductor layer 120 is formed on or disposed over the growth substrate 110. At this time, the growth substrate 110 can include defect aggregation regions 111.

The growth substrate 110 can be or include a nitride substrate, and the nitride substrate can include, for example, a gallium nitride substrate or an aluminum nitride substrate. The growth substrate 110, which is or can include a nitride substrate, can include various growth planes. In one example of this embodiment, the growth substrate 110 can have a growth plane which is either a non-polar growth plane such as an m-plane (1-100) or a-plane (11-20) or a semi-polar growth plane such as a (20-21) plane. Accordingly, a nitride semiconductor layer grown on the growth substrate 110 can have non-polar or semi-polar properties to minimize degradation in internal quantum efficiency due to spontaneous polarization.

The growth substrate 110 having the non-polar or semi-polar growth plane can be provided by growing a nitride single crystal on seed substrates using hydride vapor phase epitaxy (HYPE), followed by slicing the nitride single crystal. Accordingly, the defect aggregation regions 111 can be generated from interfaces between the plural seed substrates. The defect aggregation regions 111 can have a stripe or dot pattern depending on techniques of manufacturing the growth substrate 110. In some implementations, the defect aggregation regions 111 can have different patterns. The defect aggregation regions 111 can be exposed on an upper surface, for example, the growth plane of the growth substrate 110.

The first nitride semiconductor layer 120 can include a nitride semiconductor such as (Al, Ga, In)N and, for example, can include GaN. The first nitride semiconductor layer 120 can be grown using metal organic chemical vapor deposition (MOCVD), molecular beam epitaxy (MBE), or HYPE. The first nitride semiconductor layer 120 can be grown at a first temperature and a first pressure, and can be grown at a relatively high temperature. For example, the first nitride semiconductor layer 120 can be grown using MOCVD under conditions as shown in FIG. 6 or 7. In the example shown in FIG. 6 or 7, the first nitride semiconductor layer 120 can be grown by adjusting the temperature in the range from 1050° C. to 1200° C. and the pressure in the range of 50 Torr to 300 Torr within the MOCVD process chamber, followed by supplying at least one of H₂ gas and N₂ gas, and NH₃ and TMGa as GaN source gas to the chamber. At this time, the first nitride semiconductor layer 120 can be grown to have a thickness from 2 μm to 3 μm.

A semiconductor layer can be difficult to grow on the defect aggregation regions 111 of the growth substrate 110 due to high defect density. In addition, since two-dimensional growth is predominant in the first nitride semiconductor layer 120 grown under the aforementioned conditions, the first nitride semiconductor layer 120 can be dominantly grown on or over regions other than the defect aggregation regions 111 on the growth substrate 110. Accordingly, the first nitride semiconductor layer 120 can include pits 121 formed on the defect aggregation regions 111. As one example of FIG. 1, the pits 121 can be formed to have a V shape.

The disclosed technology is applicable to other implementations. For example, the pits 121 may not be formed in the first nitride semiconductor layer 120 according to a change in the growth conditions.

Referring to FIG. 2, a second nitride semiconductor layer 130a is formed on or disposed over the first nitride semiconductor layer 120. The second nitride semiconductor layer 130a can be grown to cover the first nitride semiconductor layer 120, and in addition, can be grown to fill the pits 121.

The second nitride semiconductor layer 130a can include a nitride semiconductor such as (Al, Ga, In)N. For example, the semiconductor nitride semiconductor layer 130a can include GaN. The second nitride semiconductor layer 130a can be grown using MOCVD, MBE, or HYPE. The second nitride semiconductor layer 130a can be grown at a second temperature and a second pressure. For example, the second nitride semiconductor layer 130a can be grown at a lower temperature than the first nitride semiconductor layer 120. In other words, the second temperature at which the second nitride semiconductor layer 130a is grown can be lower than the first temperature at which the first nitride semiconductor layer 120 is grown. The first pressure can be the same as or different from the second pressure. For example, the second nitride semiconductor layer 130a can be grown using MOCVD under conditions as shown in FIG. 6 or 7.

According to one embodiment of the disclosed technology illustrated with reference to FIG. 6, the second nitride semiconductor layer 130a can be grown by adjusting the temperature in the range of 700° C. to 850° C. and the pressure in the range of 50 Torr to 300 Torr within the MOCVD process chamber, followed by supplying at least one of H₂ gas and N₂ gas, or NH₃ and TMGa as GaN source gas to the chamber. At this time, the second nitride semiconductor layer 130a can be grown to have a thickness of 100 nm to 1000 nm.

Since the second nitride semiconductor layer 130a is grown at the second temperature, namely, at a relatively low temperature, the second nitride semiconductor layer 130a can be grown from regions where defects are present. Accordingly, the second nitride semiconductor layer 130a can be grown from the defect aggregation regions 111, and in addition, can be grown while filling the pits 121 through three-dimensional growth. Since the second nitride semiconductor layer 130a is grown while filling the pits 121, the second nitride semiconductor layer 130a may not include configurations such as the pits 121 on the surface of the second nitride semiconductor layer 130a unlike the first nitride semiconductor layer 120. Accordingly, the second nitride semiconductor layer 130a can have a substantially horizontal surface. However, since the second nitride semiconductor layer 130a is grown from the defect regions at a relatively lower temperature, the second nitride semiconductor layer 130a can have a surface roughness higher than that of the first nitride semiconductor layer 120. In one example as shown in FIG. 2, the second nitride semiconductor layer 130a has a rough surface.

Since the second nitride semiconductor layer 130a can be grown from the defect regions, the second nitride semiconductor layer 130a can potentially offset surrounding defects during the growth of the second nitride semiconductor layer 130a to decrease the defect density. Accordingly, the second nitride semiconductor layer 130a can potentially decrease the defect density of other semiconductor layers formed on or disposed over the second nitride semiconductor layer 130a in subsequent processes to achieve excellent crystallinity.

Another embodiment illustrated with reference to FIG. 7 is mostly similar to the embodiment shown in FIG. 6 bur is different from FIG. 6 in that the chamber remains at a relatively high pressure upon the growth of the second nitride semiconductor layer. In the embodiment shown in FIG. 7, the pressure used for growing the second nitride semiconductor layer 130a is higher than the pressure used for growing the first nitride semiconductor layer 120.

In the embodiment shown in FIG. 7, the second nitride semiconductor layer 130a can be grown at a pressure of 300 Torr to 500 Torr which is higher than the growth pressure of the first nitride semiconductor layer 120. The second nitride semiconductor layer 130a is grown at the relatively high pressure, thereby making it possible to more effectively induce growth of the second nitride semiconductor layer 130a on the defects.

Referring to FIG. 3, the second nitride semiconductor layer 130a is subjected to heat treatment. Through heat-treatment, surface roughness of the second nitride semiconductor layer 130 can be decreased. Accordingly, the second nitride semiconductor layer 130 can have a flat upper surface.

The second nitride semiconductor layer 130a can be subjected to heat treatment at a third pressure and a third temperature within the same chamber in which the first nitride semiconductor layer 120 and the second nitride semiconductor layer 130a were grown. At this time, the third temperature can be higher than the second temperature. For example, as shown in the graph of FIG. 6 or 7, heat-treatment can be performed by adjusting the temperature to be equal to or greater than 1000° C. and the pressure in the range of 50 Torr to 300 Torr within the MOCVD process chamber, followed by supplying at least one of H₂ gas or N₂ gas, and NH₃ and TMGa as GaN source gas to the chamber.

The second nitride semiconductor layer 130a is subjected to heat treatment at a temperature of 1000° C. or higher to achieve excellent surface quality of the second nitride semiconductor layer 130. In addition, through heat treatment, the second nitride semiconductor layer 130 can have excellent crystallinity.

In the embodiments of the disclosed technology, although the defect density can be decreased by growing the second nitride semiconductor layer 130a at a relatively lower temperature, the surface of the second nitride semiconductor layer 130a is roughened due to the low-temperature growth. However, the second nitride semiconductor layer 130 with excellent surface quality and crystallinity can be provided through heat treatment for the second nitride semiconductor layer 130a to impart excellent crystallinity to semiconductor layers grown on the second nitride semiconductor layer 130 in subsequent processes.

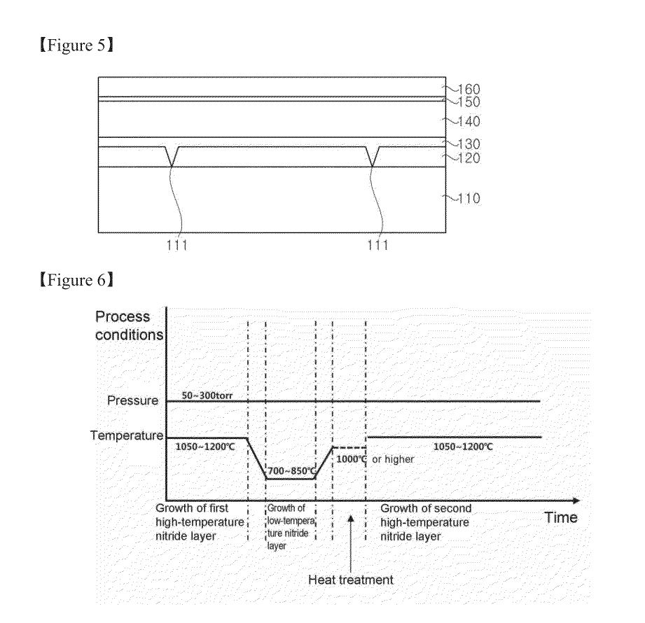

Referring to FIG. 4, a third nitride semiconductor layer 140a can be grown on the second nitride semiconductor layer 130. Accordingly, a template for semiconductor fabrication shown in FIG. 4 can be provided.

The third nitride semiconductor layer 140 is generally similar to the first nitride semiconductor layer 120. However, the third nitride semiconductor layer 140 can be doped with first conductive type impurities to form a first conductive type layer. For example, the third nitride semiconductor layer 140 can be doped with Si impurities to form an n-type layer. However, the disclosed technology is applicable for including other treatments to the third nitride semiconductor layer 140.

According to the embodiments described above, the template for semiconductor fabrication does not contain defects propagated from the defect aggregation regions 111 which can be formed on the growth substrate and has excellent surface quality and crystallinity. Accordingly, a semiconductor device to be formed on the template can have excellent properties.

Additional semiconductor layers can be grown on or over the template. Further, as shown in FIG. 5, a semiconductor light emitting device can be manufactured by forming an active layer 150 and a second conductive type semiconductor layer 160.

While one implementation of the disclosed technology has been explained above, the disclosed technology is not limited to the above and other implementations are also possible. After growing the second nitride semiconductor layer 130a, the second nitride semiconductor layer 130a can be heat-treated while the temperature of process chamber increases. In this case, the additional heat treatment process can be omitted.

Referring to FIG. 5, the active layer 150 is grown on or over the third nitride semiconductor layer 140, and the second conductive type semiconductor layer 160 is grown on or over the active layer 150.

The active layer 150 can include a multi-quantum well structure including a nitride semiconductor. In this case, elements and compositions of semiconductor layers with the multi-quantum well structure can be adjusted such that the semiconductor layers can emit light with a desired peak wavelength.

The second conductive type semiconductor layer 160 can include a nitride semiconductor such as (Al, Ga, In)N, and can be doped with second conductive type impurities to form a second conductive type layer. For example, the second conductive type semiconductor layer 160 can be doped with p-type impurities such as Mg.

The semiconductor light emitting device shown in FIG. 5 can be provided by forming the active layer 150 and the second conductive type semiconductor layer 160. The semiconductor light emitting device shown in FIG. 5 can be used as a vertical structure, a flip-chip structure, or a horizontal structure as necessary. Specific descriptions on the various structures of the semiconductor light emitting device will be omitted for brevity.

In addition, additional technical features can be applied to the semiconductor light emitting device disclosed in this patent document . For example, the semiconductor light emitting device can include an electron blocking layer (not shown), a superlattice layer (not shown), an electrode (not shown), or the like. Detailed descriptions thereof will be omitted for brevity.

In this embodiment, the semiconductor light emitting device can be manufactured by growing the semiconductor layer on the template for semiconductor fabrication as provided in this patent document. Accordingly, the light emitting device can have various advantages including low defect density, excellent crystallinity, lower forward voltage (V_{f}), and excellent leakage properties, as compared to the conventional light emitting device. Excellent leakage properties can be achieved due to low reverse current characteristics.

FIGS. 8 (a) and (b) are images illustrating a comparison between a surface of a semiconductor layer grown by a method of growing a nitride semiconductor disclosed in this patent document and a surface of a semiconductor layer grown by a comparative example. FIG. 8(a) is an image showing a surface of a semiconductor layer grown on or over a template for semiconductor fabrication not including a second nitride semiconductor layer 130, and FIG. 8(b) is an image showing a surface of a semiconductor layer grown on or over a template for semiconductor fabrication including a second nitride semiconductor layer 130.

As shown in FIGS. 8 (a) and (b), the semiconductor layer grown on the template for semiconductor fabrication including the second nitride semiconductor layer 130 has significantly excellent surface quality. For example, as shown in FIG. 8(b), the semiconductor layer grown on the template according to the disclosed technology does not include defect regions propagated from defect aggregation regions 111.

Only a few embodiments, implementations and examples are described and other embodiments and implementations, and various enhancements and variations can be made based on what is described and illustrated in this document.

What is claimed is:

1. A method of manufacturing a semiconductor light emitting device, comprising:
preparing a growth substrate having a defect aggregation region;
growing a first nitride semiconductor layer over the growth substrate;
growing a second nitride semiconductor layer over the first nitride semiconductor layer; and
growing a third nitride semiconductor layer over the second nitride semiconductor layer;
growing an active layer over the third nitride semiconductor layer; and
forming a second conductive type semiconductor layer over the active layer,
wherein the first and second nitride semiconductor layers are grown at a first temperature and a second temperature, respectively, and the first temperature is higher than the second temperature.

2. The method of claim 1, wherein the first and second nitride semiconductor layers are grown at a first pressure and a second pressure, respectively.

3. The method of claim 1, wherein the first temperature is in the range of 1050° C. to 1200° C. and the second temperature is in the range of 700° C. to 850° C.

4. The method of claim 2, further including:
performing a heat treating on the second nitride semiconductor layer at a third pressure and a third temperature.

5. The method of claim 4, wherein the third temperature is 1000° C. or higher.

6. The method of claim 4, wherein the first, second and third pressures are the same, and the first pressure is in the range of 50 Torr to 300 Torr.

7. The method of claim 4, wherein the second pressure is higher than the first or third pressures and is in the range of 300 Torr to 500 Torr.

8. The method of claim 4, further including:
growing a third nitride semiconductor layer on the second nitride semiconductor layer after heat treating the second nitride semiconductor layer,
wherein the third nitride semiconductor layer is grown at a fourth pressure and a fourth temperature.

9. The method of claim 8, wherein the fourth pressure is the same as the first pressure and the fourth temperature is the same as the first temperature.

10. The method of claim 1, wherein the first nitride semiconductor layer includes a pit formed on the defect aggregation region.

11. The method of claim 10, wherein the second nitride semiconductor layer fills the pit.

12. The method of claim 11, wherein the second nitride semiconductor layer is grown at a pressure of 300 Torr to 500 Torr and the first nitride semiconductor layer is grown at a lower pressure than the second nitride semiconductor layer.

13. The method of claim 4, wherein, after the performing of the heat treatment, the second nitride semiconductor layer has a flat upper surface.

14. The method of claim 1, wherein the growth substrate includes a nitride substrate.

15. The method of claim 14, wherein the nitride substrate includes a non-polar or semi-polar nitride substrate.

16. The method of claim 1, wherein the third nitride semiconductor layer includes a first conductive type impurity to have first conductive type properties.

17. The method of claim 1, wherein the growing of the third nitride semiconductor layer includes increasing a growth temperature of a process chamber after the growing of the second nitride semiconductor layer,
wherein the second nitride semiconductor layer is heat-treated while increasing a growth temperature of the process chamber.

18. A semiconductor fabrication template, comprising:
a growth substrate including defect aggregation regions and a non-polar or a semi-polar growth plane;
a first nitride semiconductor layer disposed over the growth substrate to form pits that in the defect aggregation regions;
a second nitride semiconductor layer disposed over the first nitride semiconductor layer to fill the pits;
a third nitride semiconductor layer disposed over the second nitride semiconductor layer and doped with impurities for determining a type of conductivity.

19. The semiconductor fabrication template of claim 18,
wherein the second nitride semiconductor layer has a surface roughness higher than the first nitride semiconductor layer.

20. The semiconductor fabrication template of claim 18,
wherein the template is substantially free of defects originated from the defect aggregation regions.
